(19) United States
(12) Patent Application Publication
(10) Pub. No.: US 2005/0251353 A1
(43) Pub. Date: Nov. 10, 2005

(54) System and method for analyzing an electrical network

(76) Inventor: Zoltan Azary, Occidental, CA (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/838,949

(22) Filed: May 4, 2004

(51) Int. Cl. G01R 29/02

(52) U.S. Cl. 702/79

(57) ABSTRACT

Systems and methods are provided that allow for accurate computation of the group delay and, if desired, phase response of an electrical network from known amplitude measurements. In one embodiment, a model that includes information regarding locations (e.g., approximate locations) of at least one of poles and zeros for an electrical network is used for computing at least one of group delay and phase response of the electrical network for a frequency range over which amplitude measurement data is unknown. Further, a transition segment may be determined for use in computing contribution to group delay over a transition between a first frequency region for which amplitude measurement data is known and a second frequency region for which amplitude measurement data is unknown. The techniques provided may be used for analyzing various types of systems, such as lowpass, bandpass, etc., and may be applied for analysis of non-minimum phase electrical networks.

### TECHNICAL FIELD

The following description relates in general to analysis of electrical networks, and more particularly to systems and methods for computing group delay and/or phase response for an electrical network from amplitude (or “magnitude”) response data.

### BACKGROUND OF THE INVENTION

Various types of electrical networks are known, such as a plurality of interconnected electrical components. Typical components include, but are not limited to resistors, capacitors, inductors, semiconductors, integrated circuits and transmission lines. Many of these networks can be successfully designed and analyzed using linear system theory. With the proliferation of electrical networks for communicating information, it is often desirable to analyze the response of an electrical network to input signals in order to, for example, determine ways to improve the performance of such electrical network. For instance, it is often desirable to compute the group delay and/or the phase response of an electrical network. As is well-known in the art, “group delay” is the derivative of phase with respect to frequency. Once such responses of the electrical network are determined, actions may be taken to compensate for (or alleviate) undesirable responses of the electrical network. For instance, certain input signals may be manipulated (prior to presenting such input signals to the electrical network) in a manner that results in the electrical network outputting a desired response for such input signals.

As an example, determination of the portion(s) of the phase response in an electrical network that is/are not linear in frequency may be desired. In general, a linear phase versus frequency amounts to a time delay, which is often not significant in terms of identifying something about the electrical network that needs to be corrected. However, if there is a phase shift occurring in the electrical network that is not linear with frequency, that can cause harm to signals that pass through the network (e.g., resulting in an undesired response). Hereafter, phase shift that is not linear with frequency will be referred to as “non-linear phase”. The term “non-linear” as used in this context is not meant to imply that the electrical network need be a non-linear system. So, if such a non-linear phase shift is known, it can be corrected for ahead of time. For example, once the non-linear phase shift of an electrical network is known, available digital filters may be used to easily remove or compensate for the phase shift before the signal is sent across the electrical network.

Generally, network analyzers are known for performing various types of operations concerning the analysis of electrical networks. Network analyzers are expensive equipment, particularly those that provide a high degree of accuracy. It is often desirable to analyze a network (e.g., compute group delay and/or phase response) from measured amplitude (or “magnitude”) data because relatively inexpensive equipment can be used to measure the amplitude data of the electrical network. For instance, a level detector or spectrum analyzer (or other device) may be used for measuring the amplitude of the frequency response of an electrical network.

A technique for computing group delay from amplitude data was proposed by Liou and Kurth in “Computation of Group Delay from Attenuation Characteristics via Hilbert Transformation and Spline Function and Its Application to Filter Design,” IEEE Transactions on Circuits and Systems, Vol. CAS-22, No. 9, September 1975 (hereafter referred to as “Liou and Kurth”). As the title of their article suggests, Liou and Kurth's proposed technique uses the Hilbert transform. In general, the Hilbert transform is a mathematical relationship between real and imaginary parts of a linear system's frequency response. Within limits, it also provides a mathematical relationship between the amplitude and phase response of a linear system. Theoretically, one may compute the phase response of a linear system, using the Hilbert transform, given only the amplitude response. Historically, attempts at implementing this computation have been less than successful. Computing the Hilbert transform requires evaluation of an integral equation (definite integral). This evaluation requires amplitude response data at all frequencies (zero to infinity), which is never available in the real world. Furthermore, the nature of the integrand is such that standard numerical integration techniques result in unacceptable errors.

In the above-mentioned article, Liou and Kurth propose a technique for computing group delay. In doing so, Liou and Kurth propose an accurate technique for evaluating the definite integral of the Hilbert transform over the frequency range where measured amplitude data is available. This involves fitting a cubic spline to the measured data and evaluating the Hilbert integral on the spline equations instead of attempting to numerically integrate the data directly. Liou and Kurth also propose a very rough mathematical approximation to be substituted at frequencies where no measured data is available. Analytic integration is used on the rough model at all frequencies where measured data is not available.

### BRIEF SUMMARY OF THE INVENTION

The above-mentioned technique proposed by Liou and Kurth provides a rough model used to generate amplitude data at frequencies outside the range of measured data. This rough model is a poor match in many cases. For instance, this rough model is inadequate when accuracies of one degree or better are desired. Further, the algorithm proposed by Liou and Kurth assumes the electrical network is a bandpass filter designed by techniques common in the art, and thus fails to address bandpass networks that result when lowpass systems are subjected to frequency conversion by mixing (hereafter referred to as “translated bandpass” systems). Finally, the prior algorithm does not provide an optimal model for types of bandpass filters that Liou and Kurth were concerned with.

Embodiments described herein provide novel techniques for analyzing electrical networks. Certain embodiments are provided herein that allow for a more accurate computation of the group delay and, if desired, phase response of an electrical network from known amplitude measurements. For example, techniques of certain embodiments provided herein have been shown to provide results having accuracies of one degree or better. Further, techniques are provided that can be used for analyzing various types of systems, including without limitation lowpass, highpass, bandstop, bandpass, allpass, translated versions thereof, and other types of systems.

At least one embodiment is provided that uses measured data and a model that includes information regarding locations (e.g., approximate locations) of at least one of (a) at least one pole and (b) at least one zero for an electrical network for computing at least one of group delay and phase response of the electrical network. By using such a model that includes this information regarding locations of pole(s) and/or zero(s), accuracy in the computed group delay and/or phase response is increased.

In accordance with certain embodiments, a transition segment is determined for transitioning between a first region of frequencies for which amplitude measurement data is known for an electrical network under analysis and a second region of frequencies for which amplitude measurement data is unknown. The transition region is used for accurately computing a contribution to group delay of the electrical network over the second region of frequencies.

Various embodiments provided herein may be implemented as hardware, as computer-executable software code stored to a computer-readable medium, and/or a combination thereof. For example, computer-executable software code may be implemented that includes code for receiving amplitude measurement data for an electrical network for at least a first range of frequencies, and code for computing a first contribution to group delay for the at least a first range of frequencies. The software may further comprise code for receiving information regarding locations of zeros and poles known for the electrical network, and code for using the locations of zeros and poles for computing a second contribution to group delay for at least a second range of frequencies that are outside the at least a first range.

In accordance with at least one embodiment, a first contribution to group delay is computed, for an electrical network under analysis, for a first range of frequencies for which amplitude measurement data is known. Additionally, a second contribution to group delay is computed, for the electrical network, for a second range of frequencies for which amplitude measurement data is not known, wherein a first part of the second contribution that is computed corresponds to a transition region from the first range to the second range.

Further, certain embodiments are provided for determining group delay and/or phase response for a non-minimum phase electrical network. While previous techniques that compute group delay based on Hilbert transforms, such as the Liou and Kurth technique, are limited solely for application to minimum phase systems, techniques are provided herein for computing group delay and/or phase response for a non-minimum phase electrical network.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated that the conception and specific embodiment disclosed may be readily utilized as a basis for modifying or designing other structures for carrying out the same purposes of the present invention. It should also be realized that such equivalent constructions do not depart from the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 shows an example system according to one embodiment;

FIGS. 2A-2C show an operational flow for one embodiment;

FIG. 3 shows an example compute logic that may be used in accordance with one embodiment for computing group delay and/or phase response;

FIG. 4 shows an example of transition regions creating a smooth transition from measured data to the system model;

FIGS. 5A and 5B show graphs illustrating test inputs for nominal amplitude response versus actual simulated response according to one example test;

FIGS. 6A-6B show a graph illustrating the amount of phase error for various different techniques that may be used for computing the phase response and the actual system phase response for the example of FIGS. 5A-5B; and

FIG. 7 shows the improvement in Error Vector Magnitude (EVM) of a signal modulated with Quadrature Phase-Shift Keying (QPSK) resulting from the application of one embodiment of the present invention.

### DETAILED DESCRIPTION OF THE INVENTION

Embodiments of the present invention provide a system and method for analyzing an electrical network. For instance, various techniques are provided for computing group delay and, if desired, phase response for an electrical network. More particularly, such techniques allow for group delay and, if desired, phase to be accurately computed for an electrical network from amplitude measurements of the electrical network. This is advantageous because amplitude measurements can be acquired using relatively inexpensive equipment, and the group delay and phase information can be derived from the amplitude measurements in accordance with the various techniques described further herein.

As proposed by Liou and Kurth, Hilbert transforms can be used to compute group delay from amplitude measurements. As mentioned above, computing the Hilbert transform involves evaluation of an integral equation (definite integral), which requires amplitude response data at all frequencies (zero to infinity). Clearly, amplitude response measurement data is not ever available in the real world over this full range (zero to infinity) of frequencies. Thus, a system model may be used for computation over the range of frequencies for which measurement data is not known.

As described further below, certain embodiments are provided that utilize the Hilbert transform to compute group delay, wherein the accuracy of computation over the modeled portion of the system is improved (e.g., over the rough model used in Liou and Kurth). That is, techniques are provided for enhancing the accuracy of the computations for the range of frequencies for which amplitude measurement data is not known (the modeled portion of the electrical network), which in turn enhance the accuracy of the full group delay. Further, this enhances the accuracy of the phase response in instances when the group delay is used to further compute such phase response. Typically, it is desired to compute group delay or phase only at those frequencies over which measured data is available, but there is nothing to prevent this technique from being used to estimate group delay or phase at other frequencies (although errors may increase in such an application to other frequencies).

In certain embodiments, when knowledge regarding the locations (e.g., approximate locations) of zeros and poles for the electrical network design under evaluation are known, this information is advantageously used in computing the contribution to group delay for the range of frequencies for which amplitude measurement data is not known (the modeled portion of the system). Thus, such information regarding the locations of zeros and poles may be included in a system model for accurately computing a corresponding contribution to group delay over the modeled region of frequencies for which amplitude measurement data is not known. Accordingly, such information regarding the locations of zeros and poles is used to form a more accurate system model for use in computing group delay and, if desired, phase response than previous system models, such as the rough system model of Liou and Kurth.

Accordingly, in accordance with one embodiment, a first technique is provided for accurately computing the group delay for an electrical network from measured amplitude data using known information about a nominal design of the electrical network. More particularly, when information regarding the locations of poles and zeros (e.g., their approximate locations) are known for the nominal design of the electrical network, this information is used to improve the accuracy of the computed group delay, which in turn improves the accuracy of phase in instances where phase is desired. As is known in the art, “zeros” (or “zero frequencies”) refer to the frequencies which excite the network resulting in zero output, and conversely “poles” (or “pole frequencies”) refer to the frequencies which excite the network resulting in infinite output. Accordingly, “locations” of such zeros and poles refers to the specific frequency points at which such zeros and poles exist for the electrical network.

Further, in certain embodiments, irrespective of whether knowledge regarding the locations of zeros and poles is known for the electrical network design under evaluation, a transition segment is provided to allow for enhanced accuracy in computations for the region of frequencies transitioning from those frequencies for which amplitude measurement data is known to those frequencies for which amplitude measurement data is not known. Use of such transition segment thus improves the accuracy of overall computed group delay beyond prior techniques for computing group delay from amplitude measurements, such as the technique of Liou and Kurth.

Accordingly, in another embodiment, a second technique is provided for improving the accuracy of the computed group delay. Such second technique may be used in cases in which the locations of poles and zeros are not known for the nominal design of the electrical network under analysis, or such second technique may, in certain implementations, be used in addition to a system model that includes information regarding the locations of poles and zeros for the nominal design. In this second technique, a transition segment is used for providing a smooth transition from the region of frequencies over which measured amplitude data is known to the region of frequencies over which measured amplitude data is not known. In other words, this transition segment is used for computing a contribution to group delay for a region of frequencies between a first region of frequencies over which a contribution to group delay can be computed using corresponding amplitude measurement data and a second region of frequencies over which a contribution to group delay is computed based on a system model (e.g., a system model that includes information regarding locations of poles and zeros, as in the first technique mentioned above, or a rough system model as proposed by Liou and Kurth, etc.). Use of a transition segment in this manner improves the accuracy of the computed group delay over previous techniques, such as the technique of Liou and Kurth.

In one embodiment, a technique is provided which determines whether the locations of poles and zeros are known for the nominal design of the electrical network being analyzed, and the appropriate ones of the above-mentioned first and second techniques is applied. For instance, if information regarding the locations of poles and zeros are known for the nominal design, a system model may be determined that includes such information, and such system model may be used for computing a contribution to group delay for a region of frequencies over which amplitude measurement data is unknown for an electrical network under analysis. In certain embodiments, if the locations of poles and zeros are known, use of the transition segment technique may be omitted. That is, the transition segment technique may be reserved for use in situations in which knowledge of the locations of poles and zeros are not known for the electrical network (e.g., to improve the accuracy of a rough system model that is used for computing a contribution to group delay over the region of frequencies over which amplitude measurement data is unknown), or when the differences between the nominal and actual locations are large. However, in certain other embodiments, use of the transition segment technique may be used even in situations in which a more accurate system model is developed with information regarding locations of poles and zeros.

Further, implementations of the above techniques are provided herein to allow for group delay and, if desired, phase to be computed for any of various different types of electrical networks, including lowpass, highpass, allpass, bandstop, bandpass (including translated bandpass) and all other types of systems. In the field of filter design, the concepts of “transmission zeros” at “zero” and “infinity” are often used. These concepts correspond to zeros and poles, respectively, with each being located at zero frequency. The rough system model used by Liou and Kurth is equivalent to a system with “β” poles and “α” zeros, all located at zero frequency. It appears Liou and Kurth either failed to realize the pole/zero model implied, or perhaps did not consider the distinction important. By realizing this fact, and by generalizing the algorithm to account for both zeros and poles at arbitrary locations, the technique can be extended to analyze many other types of systems (such as the translated bandpass system), as described further below. It is even possible to analyze “allpass” systems with this technique. For example, translated bandpass systems may be approximated by creating a model with ‘β’ poles located at +jω^{c} with or without ‘β’ additional poles located at −jω^{c}, where ω_{c} is the center frequency of the bandpass system. Similarly, bandstop systems may be modeled with “α” all located at the center frequency of the system. Details of how to accommodate other types of systems are provided further below.

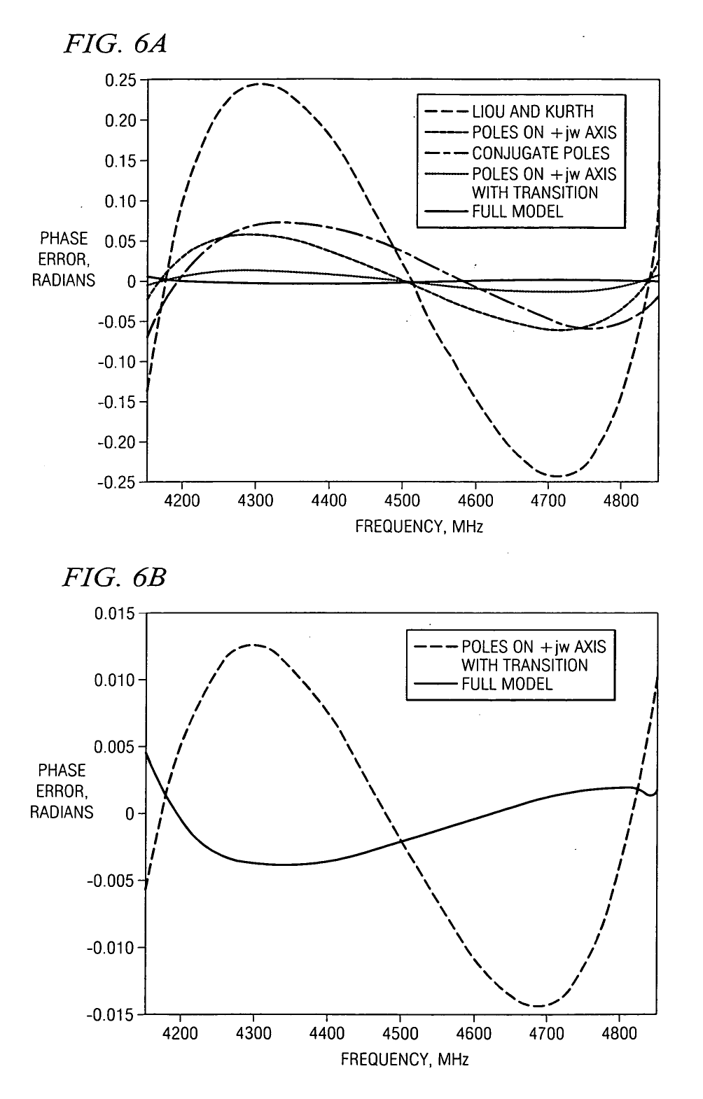

It can be shown that the extension to measured data proposed by Liou and Kurth is equivalent to a system model containing some number of poles and zeros, all located at zero frequency. The number of zeros and poles used correspond to the parameters α and β respectively, as defined by Liou and Kurth. While this provides a rough model for some types of bandpass systems, it does not work well for other systems such as translated bandpass, bandstop or allpass. In fact, the technique of Liou and Kurth does not match the types of bandpass systems in which they were interested particularly well either. For instance, while the types of bandpass filters they were designing typically included zeros at zero frequency, all the poles are clustered around the center of the filter passband, making their model with poles at zero frequency a suboptimal estimate. From the viewpoint of Liou and Kurth extensions, it is not obvious how to improve the model to analyze translated bandpass systems. From the system model viewpoint presented herein, it is logical to propose shifting the group of poles at zero frequency along the +jω axis to the center frequency of the bandpass system. Results obtained using this method are contained here (see FIG. 6A). The system model thus constructed does not represent a physically realizable system, since it contains complex poles that do not occur in conjugate pairs. This problem is not obvious using the Liou and Kurth viewpoint for extending measured data, but is readily apparent from the system model viewpoint proposed herein. Based on the later viewpoint, it can be concluded that a more accurate rough model for a translated bandpass system would have some number of complex conjugate pole pairs, all located on the jω axis at the center frequency of the bandpass system. Further, this model would also contain some number of zeros, their locations computed using techniques described below. As noted elsewhere herein, if the frequency translation amount is large compared to the bandwidth of the lowpass system, it is not necessary to add conjugate poles and related zeros. Using similar reasoning, and knowledge about mathematical transformations commonly used to convert lowpass systems (See e.g., “Digital Filters: Analysis and Design”, Andreas Antoniou, copyright 1976 McGraw Hill, ISBN 0-07-002117-1, Chapter 5, Section 7, which describes an example of these transformations) other rough models can be designed. Highpass systems can be modeled with one or more zeros located at zero frequency. Bandstop systems are modeled with one or more zeros or conjugate pairs of zeros located at the center of the stopband.

In accordance with certain embodiments, a first contribution (τ₁) to group delay is determined for the region of measured amplitude data acquired for the electrical network. A second contribution (τ₂) to group delay is determined for the region outside the range of measured amplitude data. The first and second contributions may then be summed to determine the total group delay (τ). Because the second contribution (τ₂) is for the region outside the range of measured amplitude data, a model of the system is used for determining such second contribution (τ₂). In the instances in which information regarding the locations of poles and zeros are known for a nominal design of the electrical network, this information may be used for improving the system model used in order to improve the accuracy of the computed second contribution (τ₂), as described further below.

In certain embodiments, a transition segment is proposed for use in improving the accuracy of the computed second contribution (τ₂). Again, such transition segment provides a smooth segment that transitions from a first region of frequencies over which amplitude measurement data is known to a second region over which amplitude measurement data is unknown. More particularly, one portion (τ_{2B}) of a contribution to group delay for the transition segment for the region outside the range of measured data is computed with improved accuracy. Additionally, another portion (τ_{2A}) of the second contribution to group delay is computed for the portion of the region outside the range of measured data that is outside the transition segment. The contributions of the transition segment (τ_{2B}) and the remaining portion of the region outside the range of measured data (τ_{2A}) may be summed to compute the second contribution (τ₂) for the total region outside the range of measured data.

Further, certain embodiments are provided for determining group delay and/or phase response for a non-minimum phase system. Previous techniques for using the Hilbert transforms for determining group delay and/or phase response based on amplitude measurement data worked only for minimum phase systems. Techniques are provided herein to compute the appropriate adjustment to the phase response for an electrical network that is a non-minimum phase system. Further, the group delay can be accurately determined (e.g., from the phase) for such a non-minimum phase system.

A. Overview of Hilbert Transforms

While Hilbert transforms are known (see e.g. “The Hilbert Transform, Mathias Johannson, Master Thesis in Mathematics/Applied Mathematics, Vaxjo University”), a brief overview of the Hilbert transform is now provided for convenience. Hilbert transforms are not difficult to understand if a few simple facts about the Fourier transforms of even and odd functions are recalled (of course, the below overview applies equally to Fourier and Laplace transforms).

First, the definition of an even symmetric function is that
χₒ(t)=χₑ(−t), where χₑ is the even symmetric time function and t is time. An odd symmetric function has the property that
χ₀(t)=−χₒ(−t), where χₒ is the odd symmetric tine function.

Any arbitrary function, x(t) can be decomposed into even and odd symmetric parts:

$$\begin{matrix}{χ}_{e} ( t ) = \{ \begin{matrix}\frac{1}{2} [ χ ( t ) + χ ( - t ) ] & ; & t \neq 0 \\ & ; & \\ x ( t ) & ; & t = 0\end{matrix} \\ and \\ {χ}_{o} ( t ) = \{ \begin{matrix}\frac{1}{2} [ χ ( t ) - χ ( - t ) ] & ; & t \neq 0 \\ & ; & \\ 0 & ; & t = 0\end{matrix}\end{matrix}$$

also, by definition
χ(t)=χₑ(t)+χₒ(t)

Furthermore, if (t) is restricted to being causal (i.e. (t)≡0 for t<0), then the entire time function can be recovered from only the even part:

$$χ ( t ) = \{ \begin{matrix}0 & ; & t \leq 0 \\ {χ}_{e} ( 0 ) & ; & t = 0 \\ 2 {χ}_{e} ( t ) & ; & t \geq 0\end{matrix}$$

The even symmetric part of a causal time function is not causal (except in the degenerate case where the entire causal time function is zero). Now, recall that the Fourier transform of an even time function is entirely real and the transform of an odd time function is purely imaginary. This allows the even and odd parts of an arbitrary time function to be associated with the real and imaginary parts of its Fourier transform:
χ(t) [symbol] X(jw)
χₑ(t) [symbol] R{X(jw)}, where j is square root of −1, ω is frequency, and the χₑ(t) [symbol] ℑ{X(jw)}
   double-arrow symbol signifies a fourier transform pair.

Now assume that the real part of X(jω) is available, and that X(t) is known to be a causal function. Since the inverse transform of R{X(jω)} is the even time function, χₑ(t), it is therefore possible to recover X(t) from the real part of its Fourier transform. Once X(t) is recovered, taking the Fourier transform of X(t) yields the complete Fourier transform, including the imaginary part. This process then allows recovery of the imaginary part of a transform, given only the real part (again, assuming the underlying time function is causal).
R{X(jω)} [symbol] χₑ(t) [symbol] χ(t) [symbol] X(jω) [symbol] ℑ{X(jω)}

Above, it has been shown that for causal time functions, the imaginary part of the fourier transform may be recovered from the real part. This does not yet explain how phase is recovered from magnitude. To accomplish this, logarithms of complex numbers are involved. Recall that the natural logarithm of a complex number has for its real part, the logarithm of the absolute value of the complex number. The imaginary part of the logarithm is equal to the angle of the complex number:

$$ln ( a + jb ) = ln \vert a + jb \vert + j ∠ ( a + j b ) = ln \sqrt{{a}^{2} + {b}^{2}} + j {tan}^{- 1} \frac{b}{a}$$

Therefore, taking the logarithm of the transform X(jω) yields
G(jω)=lnX(jω)=ln|X(jω)|+∠X(jω)

Now, G(jω) can be thought of as a Fourier transform in its own right, which is associated with time function, g(t). For purposes of this discussion, g(t) has no real physical meaning, other than the fact that it is the inverse transform of g(jω). It is simply a means to a further end. This time function is not necessarily causal, but for the time being let us assume (or more precisely, require) that it is. Under this assumption, it is possible to recover the imaginary part of G(jω) from its real part:
R{G(jω)} [symbol] gₑ(t) [symbol] g(t) [symbol] G(jω) [symbol] ℑ{G(jω)}

This equates to
ln|X(jω) [symbol] gₑ(t) [symbol] g(t) [symbol] G(jω) [symbol] ∠X(jω)

This process has apparently recovered the phase of X(jω) from the logarithm of its magnitude. There was, however, an assumption made in this process that G(jω) was the transform of a causal time function. It is beyond the scope of this overview to explain, but it turns out that this assumption is equivalent to assuming that X(jω) is a minimum phase function.

For continuous time functions, it would appear that it is necessary to compute an inverse fourier transform followed by a forward transform to recover phase from magnitude. The Hilbert transform is usually derived in a completely different manner, and results in a single integral equation however. The derivation presented above provides an intuitive understanding of the Hilbert transform, but is not convenient for computational purposes. See “The Hilbert Transform”, Mathias Johannson, Master Thesis in Mathematics/Applied Mathematics, Vaxjo University for the common derivation of the Hilbert transform integral:

$$∠ H ( j ω ) = \frac{1}{π} {\int }_{- ∞}^{∞} \frac{ln \vert H ( j η ) \vert}{ω - η} ⅆ η ,$$

where H is the system response being analyzed, and n is the variable of integration.

From this, it appears necessary to have magnitude information at all frequencies in order to compute phase. Examining the integrand in more detail, it will be noticed that the log-magnitude is “weighted” by a factor (ω-n) in the denominator that is related to how close the variable of integration is to the frequency of interest. It would seem then that information about the magnitude response at frequencies far from the frequency of interest is of less importance than that close by. Indeed, it is possible to use measured amplitude data near the frequency range of interest, and substitute estimates for amplitudes at far-away frequencies. Further, the region of transition from frequencies at which the measured amplitude data is known to the region at which amplitude data is not known has greater impact on the accuracy of this computation than do frequencies for which amplitude data is not known which are further from such transition region.

B. Practical Aspects of Computing Hilbert Transforms

The Hilbert transform for continuous time systems is defined by the integral:

$$𝔍 \{ G ( j ω ) \} = - \frac{1}{π} {\int }_{- ∞}^{∞} \frac{ℜ \{ G ( j η ) \}}{ω - η} ⅆ η$$

where R{·} and ℑ{·} represent the operations of taking real and imaginary parts of a complex number. It should be recalled that the real part of G is actually the log-magnitude of the system being analyzed, ln|H|. The data which is usually available in the real world is samples of the magnitude (or “amplitude”) of H over some limited range of frequencies. It is tempting to use numerical integration on the sampled data, but this has two serious drawbacks:
1. Numerical integration will be inaccurate over the range of frequencies where the denominator of the integrand, (ω-η) is very small; and
2. The range of integration is infinite, and there is no allowance for the effect of system response outside the range of measured data.

These problems are mitigated by applying the following techniques described by Liou and Kurth:
1. A mathematical model can be fit (e.g., via cubic spline) to the measured data, allowing analytic integration to be performed. Evaluation of the resulting definite integrals gives meaningful values for problem areas where the denominator of the integrand is small or vanishes.
2. A mathematical model can be created to estimate the behavior of the system outside the range of measured data. This model is also analytically integrated, yielding reasonable values for the contribution of the system response over frequencies beyond the range of measured data.

Liou and Kurth apply an additional twist to the overall algorithm. The mathematical model to be integrated outside the range of measured data turns out to be difficult (or impossible) to integrate to the upper limit, ∞. By taking the derivative of G, with respect to jω, a new transform function is created for which the real part is the group delay of H, and the imaginary part is the derivative of log-magnitude:

$$\frac{ⅆ}{ⅆ j ω} G ( j ω ) = τ ( ω ) - j {A}^{′} ( ω )$$

where τ(ω) is group delay as a function of frequency and

$${A}^{′} ( ω ) = \frac{ⅆ}{ⅆ ω} ln \vert H ( j ω ) \vert .$$

With this change, the Hilbert transform can be used to compute group delay from the derivative of log-magnitude. Conveniently, it turns out that the definite integrals resulting from this change are easily evaluated. Furthermore, the fact that group delay is computed by analytically evaluating definite integrals, means that the results are smooth and contain as much resolution as allowed by a computer's floating point library. This makes it possible to perform accurate numerical integration on the resulting group delay to recover values for phase.

C. Example Embodiments

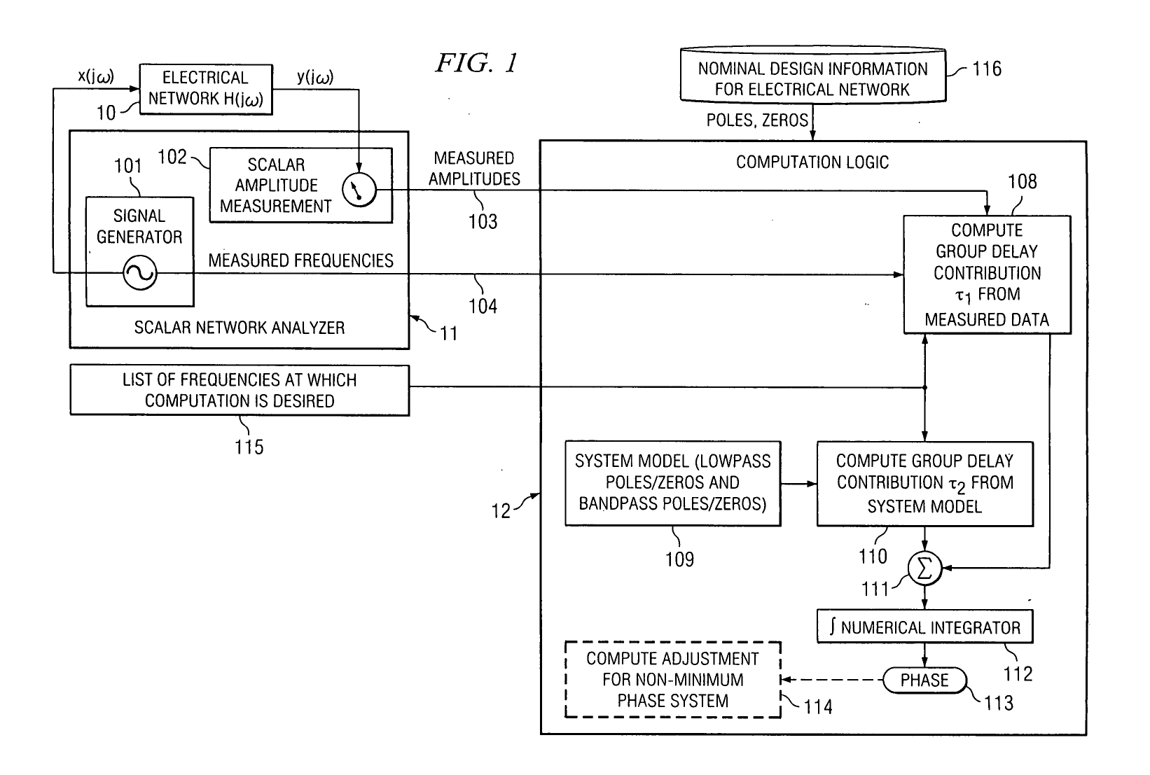

FIG. 1 shows an example system according to one embodiment. The example system of FIG. 1 includes electrical network 10 that is being analyzed. Such an electrical network 10 may, as examples, include various types of filters, amplifiers, mixers, transmission lines, and/or other interconnected electrical components (e.g., capacitors, resistors, inductors, integrated circuits, etc.). Such an electrical network's transfer function is commonly represented as H(jω), wherein j is \sqrt{−1} and ω is frequency. In a typical electrical network, H(jω) may be represented by formula:

$$H ( j ω ) = \frac{( j ω - {Z}_{1} ) ( j ω - {Z}_{2} )}{( j ω - {P}_{1} ) ( j ω - {P}_{2} )} ,$$

where Z₁ and Z₂ are zeros of the network and P₁ and P₂ are poles of the network. This is, of course, just one example and there may be a different number of poles and zeros, so the number of poles and zeros may vary independently between zero and some large value. Accordingly, whenever jω is equal to one of the poles, the denominator of the above formula is zero (0) and thus the result of this fraction becomes infinite; and whenever jω is equal to one of the zeros, the numerator of the above formula becomes zero and thus the result of this fraction becomes zero (0). In practice, poles and zeros cannot be placed directly on the jω axis and the actual response never becomes identically zero or infinity.

In analyzing electrical network 10, signal generator 101, which may be part of scalar network analyzer 11, generates input signals X(jω) of various frequencies, which are input to electrical network 10. That is, signal generator 101 generates signals X(jω) of various frequencies at a known amplitude. Responsive to such input signals, electrical network 10 outputs the output signals Y(jω). Scalar amplitude measurement device 102 measures the amplitude (or “magnitude”) of output signals Y(jω). Scalar amplitude measurement device 102 may be a power meter, level detector, or spectrum analyzer, as examples. Advantageously, devices that are relatively inexpensive are capable of accurately measuring scalar amplitude of the response Y(jω) of electrical network 10.

In certain implementations, the systems used are bandpass systems. For example, signal generator 101 and electrical network 10 may, in some instances, be part of a single equipment, and may include baseband signal generator (sometimes referred to as an arbitrary waveform generator), a local oscillator, an I/Q modulator and RF or microwave output chain that may contain additional mixers, filters, amplifiers, etc. In order to generate accurate wideband modulated signals, non-linear variations in phase (or equivalently, variations in group delay) should be removed from the system. If the phase variations are known, the baseband signal can be pre-distorted to compensate for these variations. Non-linear phase variations may be generated in the baseband or RF/microwave sections of the signal generator. In many cases, a majority of the variations are due to anti-alias filtering performed in the baseband section. Filters, amplifiers, attenuators and other components in the RF/microwave sections also contribute to non-linear phase variations, but often to a lesser degree.

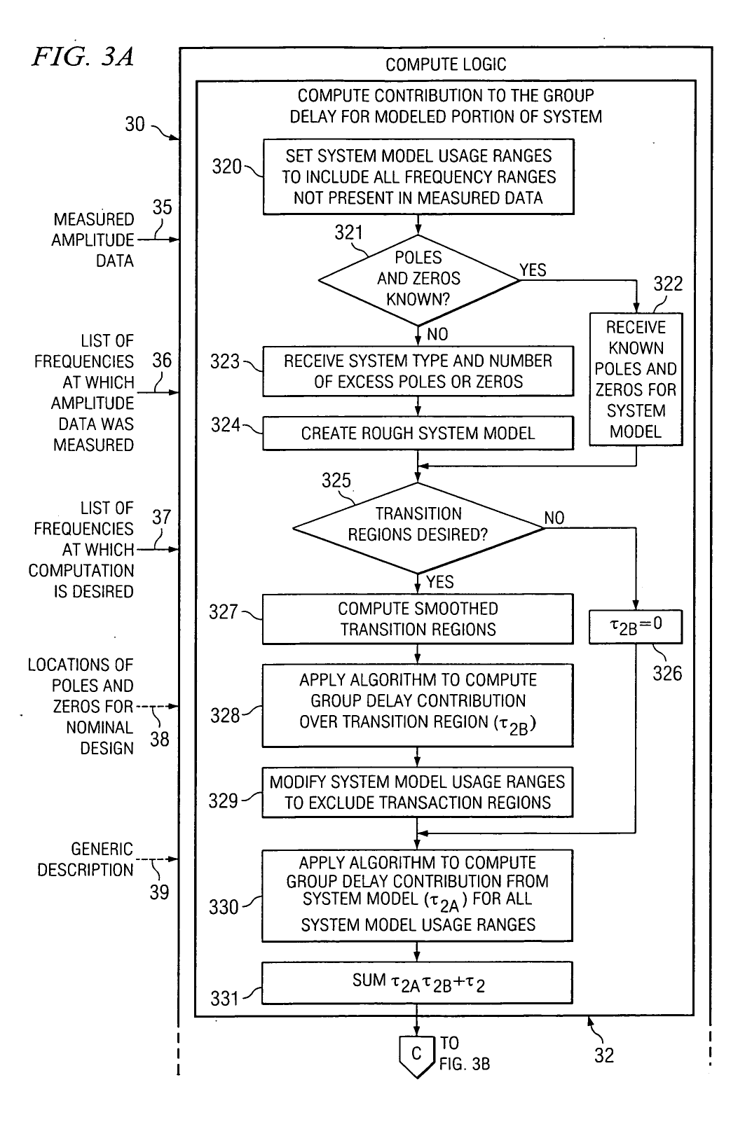

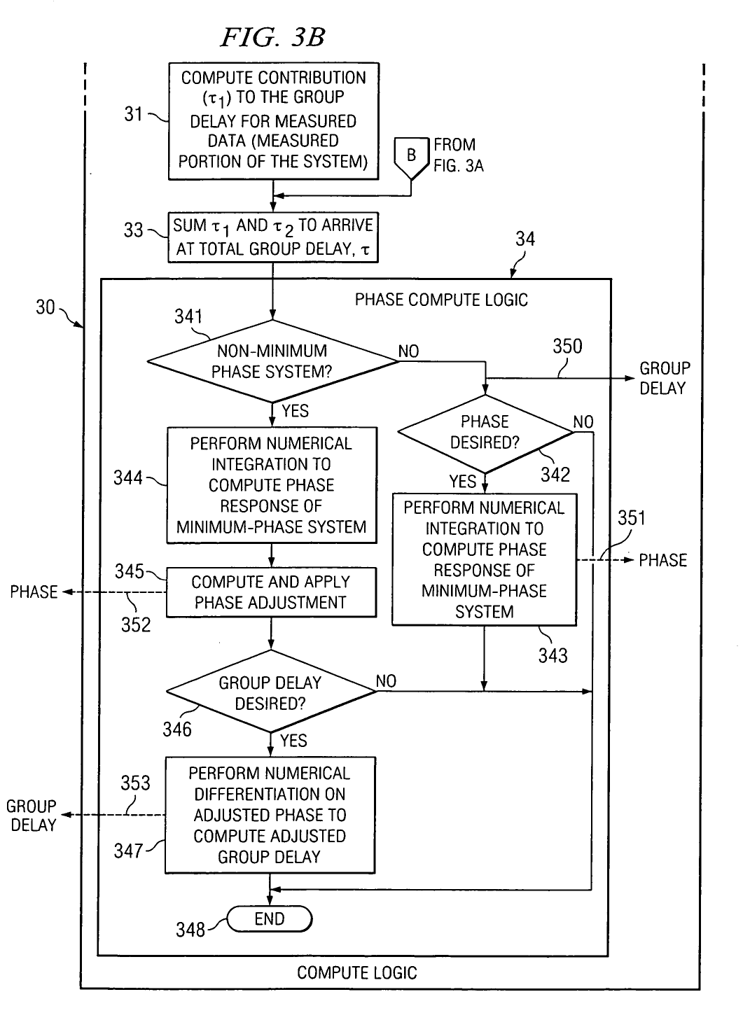

The system of FIG. 1 also includes computation logic 12, which is operable to use the scalar amplitude measurement data 103 of device 102 to accurately compute group delay and, if desired, phase response of electrical network 10 using the techniques described herein. Thus, computation logic 12 receives the scalar amplitude measurement 103 that is computed by scalar amplitude measurement device 102 and computes the group delay and, if desired, the phase response, as discussed further below. An example implementation of computation logic 12 in accordance with one embodiment is shown in FIG. 3 (as computation logic 30), which is discussed below.

In general, scalar amplitude measurement 103 is the magnitude of H(jω), i.e.,

$$\vert H ( j ω ) \vert = \frac{scalar amplitude measurement of Y ( j ω )}{\vert X ( j ω ) \vert} .$$

Of course, this measurement may be made at many frequencies, resulting in many different values of |H(jω)| at different values of ω. As shown in FIG. 1, this array of amplitude measurement information 103 and identification of the measured frequencies 104 (the frequencies of the input signals that generated the corresponding measured responses) are input to computation logic 12.

Additionally, a list 115 of frequencies at which group delay and/or phase is desired to be computed are input to computation logic 12 in certain embodiments. As further shown in the example of FIG. 1, in accordance with certain embodiments, nominal design information 116 for network 10 may be available from which a list of the known locations of poles and zeros may be supplied to computation logic 12. As described further below, computation logic 12 computes (block 108 of FIG. 1) a first contribution (τ₁) to group delay for the region of measured data acquired for electrical network 10. That is, first contribution (τ₁) is computed for the range of frequencies 104 over which measurements were made by scalar amplitude measurement device 102. Computation logic 12 further computes (block 110 of FIG. 1) a second contribution (τ₂) to group delay for the region outside the range of measured data. That is, second contribution (τ₂) is computed for the modeled region of the network, using model 109. The first and second contributions are then summed (block 111 of FIG. 1) to determine the total group delay (τ).

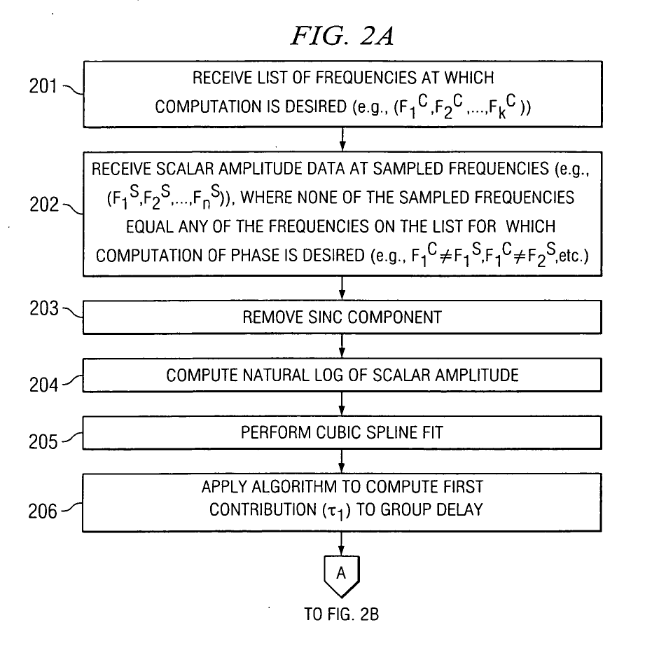

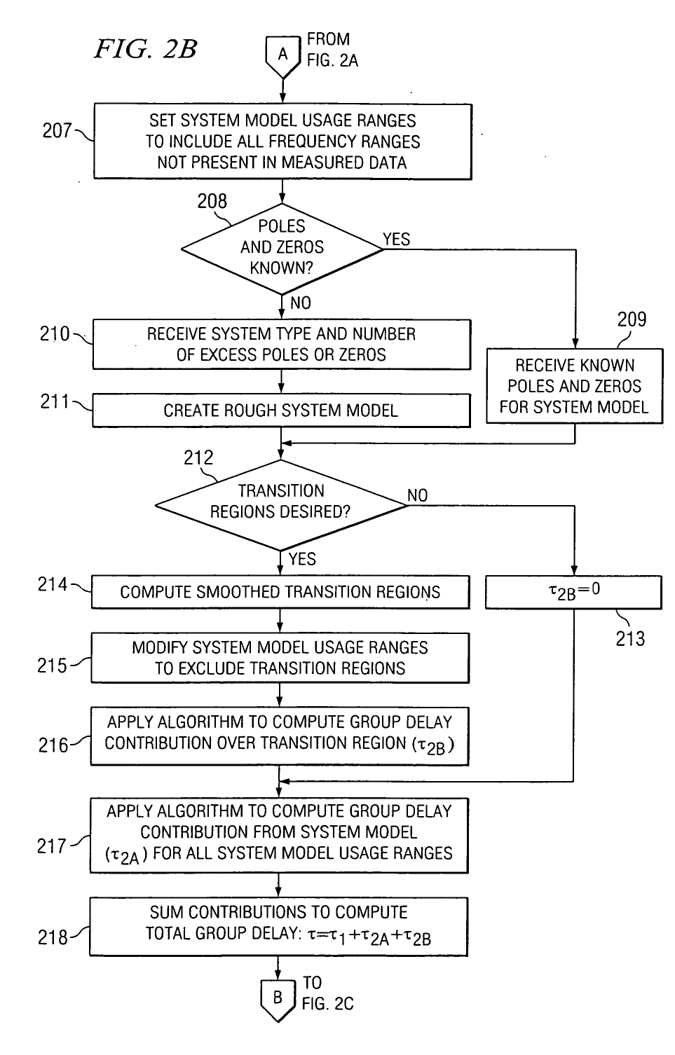

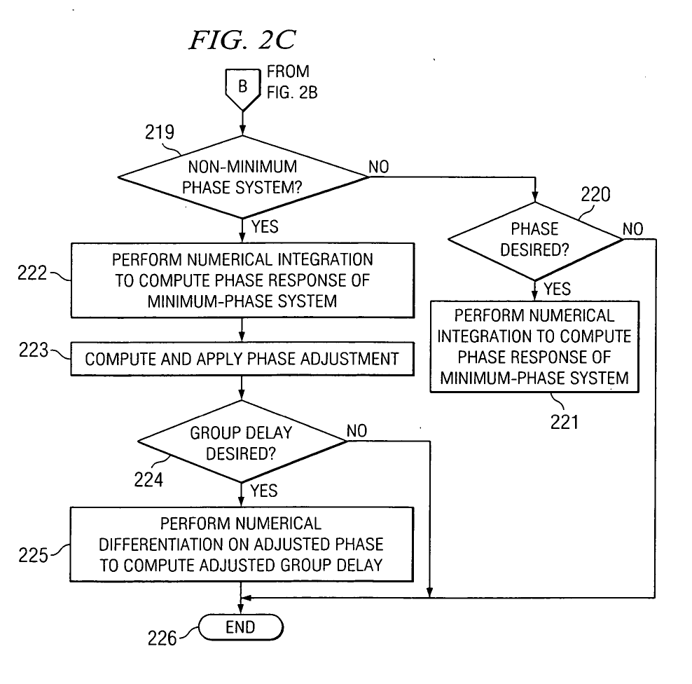

Because the second contribution (τ₂) (computed in block 110 of FIG. 1) is for the region outside the range of measured data, a model 109 of electrical network 10 is used for determining such second contribution (τ₂). In instances in which the locations of poles and zeros are known for a nominal design of the electrical network 10 (as in known design information 116 of FIG. 1), this information may be used for improving the system model 109 used in order to improve the accuracy of the computed second contribution (τ₂) in block 110, as described further below. In certain instances (e.g., in which information 116 is not available for network 10), other approximations of the electrical network may be used (as described below in connection with operations 210 and 211 of FIG. 2B). Additionally, in certain implementations described below, a transition segment is proposed for use in model 109 for improving the accuracy of the computed second contribution (τ₂) over prior techniques (such as the technique of Liou and Kurth).

In the example implementation of FIG. 1, logic 108 may compute the first contribution τ₁ to group delay for the measured data region using the Hilbert transform in the manner described by Liou and Kurth. More particularly, as described further below in connection with operations 203-206 of example process of FIG. 2A), the natural log of the measured amplitude data 103 is computed. The computed natural log is used to compute a cubic spline fit, which generates coefficients that are used in logic 108 for computing the first contribution τ₁ to group delay. Thus, this first contribution τ₁ to group delay is obtained using the measured data 103.

System model 109, along with the list 115 of frequencies at which group delay is desired, are input to block 110 and used to compute a second contribution τ₂ to group delay. Accordingly, this second contribution τ₂ is for the region of frequencies outside those for which measured data 103 was obtained. The first contribution τ₁ of block 108 and second contribution τ₂ of block 110 are summed in block 111 to compute the total group delay τ for electrical network 10. Such group delay τ is used by numerical integrator 112 to compute the phase response 113 for electrical network 10 at the desired frequencies listed (in list 115). That is, numerical integration is performed on the group delay τ to compute the phase response 113.

In certain implementations, logic 114 is also included to compute the appropriate adjustment to such phase response 113 for a non-minimum phase system. That is, as described above, the Hilbert transform produces correct results only for a minimum phase system. Techniques are described further below, which may be employed in block 114, to enable the result of the Hilbert transform to be appropriately adjusted for an accurate computation of phase response for a non-minimum phase system. For non-minimum phase systems where group delay is desired instead of phase, the corrected phase is then numerically differentiated to arrive at the correct group delay.

Turning to FIGS. 2A-2C, an operational flow for one embodiment is shown. More particularly, the operational flow of FIGS. 2A-2C provides one example of the operation of computation logic 12 of FIG. 1 in accordance with certain embodiments thereof. In operational block 201 (FIG. 2A) a list (e.g., list 115 of FIG. 1) of frequencies at which computation (e.g., of group delay and/or phase) is desired. Such list of frequencies may be represented as (F₁^{C}, F₂^{C}, . . . , Fₖ^{C}), which is a list of k frequencies for computation (F^{C}). Such list of frequencies may be received via user input, a file, or any other desired technique. In operational block 202, scalar amplitude data (e.g., data 103 of FIG. 1) at sampled frequencies (e.g., frequencies 104 of FIG. 1) is received. The sampled frequencies at which such scalar amplitude data is acquired may be represented as (F₁^{S},F₂^{S}, . . . ,Fₙ^{S}), which is a list of n sampled frequencies (F^{S}). In this example embodiment, none of the sampled frequencies (F₁^{S}, F₂^{S}, . . . , Fₙ^{S}) equal any of the frequencies at which computation is desired (F₁^{C}, F₂^{C}, . . . , Fₖ^{C}). An example technique for achieving this is to create a first grid of sampled frequencies and then a second (typically more dense) grid of frequencies at which computation is desired, where the second grid is offset from the first grid so that none of the frequencies line up with each other. In this example embodiment, problems may arise in the computations of the Hilbert integral if the sampled frequencies and frequencies at which computation is desired match (because they result in having zero in the denominator of the integrand at one of the limits of integration: this limitation exists in the algorithm proposed by Liou and Kurth and is not a limitation specific to embodiments of this invention).

In operational block 203, the sinc component is removed from the received amplitude measurement data. In some cases, the measured amplitude response may include a sinc roll-off component. For example, in characterizing phase response in signal generators, there may be a component in the amplitude response due to the digital-to-analog conversion process which has a characteristic “sinc” shape. In some baseband generators, the baseband signal is oversampled at a 4× rate, and the sinc component is minor, but in other cases there is no oversampling and the sinc component is a significant part of the measured amplitude response. This component does not add to non-linear phase response. That is, this sinc component is known to have linear phase and is often not of any interest in determining phase response. Thus, it may be beneficial to remove the sinc component. Following are two ways for dealing with this sinc component (in operational block 203):
1. Add the known sinc response behavior to the model used to extend data beyond the measured range; or
2. Remove the known sinc response from measured data before processing.

Similarly, any other amplitude components that are known to be part of the amplitude response, but which do not contribute significantly to non-linear phase response may be either fully modeled (by the flexible model described herein, e.g., model 109 of FIG. 1), or removed prior to further processing.

In operational block 204, the natural log of the scalar amplitude measurement (having the sinc component removed therefrom) is computed. As explained above, the natural logarithm of the scalar amplitude component is required if phase (or group delay) is to be computed.

In operational block 205, a cubic spline fit is applied to the scalar amplitude measurement data. For instance, Liou and Kurth propose a technique in which a cubic spline is fit to the measured data, and the Hilbert integral is evaluated on the spline equations instead of attempting to numerically integrate the data directly, which improves the accuracy of the result over the region of measured data. Thus, the measured amplitude data may be fit to spline segments in the same form as proposed by Liou and Kurth.

In operational block 206, an algorithm is applied to compute the first contribution (τ₁) to group delay (i.e., the contribution from the region of sampled frequencies). More specifically, the portion of the algorithm proposed by Liou and Kurth which applies to the set of measured response data may be used in this operational block 206.

In operational block 207 (FIG. 2B), the range of frequencies over which the system model is used to extend measured data is initially determined. The initial list contains all those frequencies between 0 and ∞ which are not part of the range of measured data. For example, if measured data is available between 0 and f₁, then the initial setting would contain a single range from f₁ to ∞ which are not part of a range of measured data. If measured data were available from f₁ to f₂, the initial setting would contain two ranges, from 0 to f₁ and from f₂ to ∞. As a final example, if measured data were available from f₁ to f₂, and from f₃ to f₄ (frequencies assumed to be in ascending order), there would be three ranges in the initial setting, from 0 to f₁, from f₂ to f₃, and from f₄ to ∞. As described further below, a system model is used for computing a group delay contribution from the range(s) of frequencies for which measured amplitude data is not available, and in certain implementations transition segments may be used for transitioning between each region of measured amplitude data and the adjacent regions over which measured amplitude data is not known. For instance, in the last example above, a transition segment may be used for transitioning from the system model to the beginning of the first region of measured data (at f₁), and a transition segment may be used for transitioning from the ending of the first region of measured data (at f₂) to the system model; and a transition segment may be used for transitioning from the system model to the beginning of the second region of measured data (at f₃), and a transition segment may be used for transitioning from the ending of the second region of measured data (at f₄) to the system model.

In operational block 208, a determination is made as to whether locations of poles and zeros are known for the nominal design of the electrical network under analysis. For instance, a determination is made whether information 116 of FIG. 1 is known for electrical network 10. If this information is known, operation advances to block 209 whereat the computation logic receives the known (approximate) zero and pole locations of the nominal system for use in modeling the system (model 109 of FIG. 1) for computing a second contribution (τ₂) to group delay from the region of frequencies for which amplitude measurement data is not known.

If determined in block 208 that information regarding the locations of poles and zeros are not known for the nominal design of the electrical network under analysis, operation advances to block 210 whereat the system type (lowpass, bandpass, highpass, bandstop, etc.) and number of excess poles and/or zeros are received, and such excess poles are all set to a single frequency as determined below. For instance, if the system has two zeros and five poles, there would be three excess poles, and this number of excess poles are set at single frequency. This number of excess poles or zeros that are each set at the same frequency, are used in block 211 to create the system model (model 109 of FIG. 1) to be used in this instance, instead of the more detailed list of the actual locations of poles and zeros used in block 209 for computing the system model.

The type of system determines whether poles or zeros are to be used. Lowpass and bandpass systems are modeled with excess poles. Bandstop and highpass systems are modeled with excess zeros. The frequency at which poles or zeros are located when constructing the rough system model is determined by the type of system being measured. For lowpass and highpass systems all poles or zeros are placed at zero frequency. For bandpass and bandstop systems all poles or zeros are placed on the jω axis at the center frequency of the system.

From block 209 or block 211, operation advances to block 212 whereat a determination is made whether transition regions (or “segments”) are desired to be used. Thus, in operational block 212, a determination is made whether to create transition regions between measured data and the system model. Transition regions may be used regardless of whether the system model is constructed with knowledge of poles and zeros, as determined by block 208. Transition regions may be of more benefit when used with a rough system model (such as created in block 211); however, this does not preclude their use with the more accurate model (created in block 209). If a transition region is not desired to be used, then operation advances to block 213 whereat contribution τ_{2B} is set to 0 in this example implementation. That is, when the decision is made to forgo the creation of transition regions in operational block 212, flow passes to block 213 where τ_{2B} is set to zero since transition regions are not used.

On the other hand, if a transition region is desired to be used, then operation advances to block 214 where a smoothed transition region is determined for use in the system model. To understand the value of adding transition regions, recall that the Hilbert Transform integral used in this algorithm requires that a formula be developed to model the system being analyzed. This formula is used to represent the system at frequencies outside the range of measured data. More specifically, the formula must model the derivative of the logarithm of the system's magnitude (or “amplitude”) response. In other words, it is important that this model accurately reflect the system's derivative of log-magnitude. The model need not match the system magnitude response, just the derivative of log-magnitude (hereafter referred to as DLM).

The rough model proposed by Liou and Kurth results in a significant discontinuity in DLM between the end points of measured data and the rough model. This causes significant errors in computation of group delay and phase. By fitting one or more cubic spline segments between the end of measured data and points further out on the rough model, a smooth transition can be made between measured data and the rough model. Numerical simulations have proven that this significantly reduces errors in computed group delay and phase, as discussed further below. This technique is most valuable when little is known about the system being analyzed.

The integrand involved in the Hilbert transform contains the derivative of the log-magnitude frequency response. It follows that the model used to extrapolate system behavior should have a log-magnitude derivative that closely matches the real world system being analyzed. To this end, plots of this derivative overlaid with the derivative estimate for frequencies outside the measured data were analyzed. When the measured data does not include much of the filter skirts, there is usually a significant discontinuity between the end of the measured data and the value of the extrapolation at that point. Again, the accuracy of the algorithm can be improved if a smooth transition can be created between the end of measured data and the filter skirt estimates.

While a cubic spline fit is one example technique, any technique which creates a smooth transition curve between the end of measured data and the system model may be used, as long as it is possible to evaluate the resulting Hilbert integral equations. Examples of other transition functions are polynomials of varying degree and segments of exponential functions. The width of the transition region is chosen by trial and error or other technique to aid in obtaining a smooth transition. In this example embodiment, a cubic spline section is used to make the transition (block 214). This allows control of the end slopes of the data as well as end points themselves. The only task left then, is choosing the width of the transition region.

In this example technique, the spline is constructed on the derivative function, rather than on the log-magnitude function directly. Two spline elements are created to allow the end points and end slopes to be aligned with measured data on one end, and the system model on the other. The function values input to the spline fit are the last DLM value available from user data (or, more accurately, the endpoint value from the spline that was fit to measured data) and two equally spaced points on the system model. The exact spacing of the two points are determined by trial and error or other method to achieve a smooth transition. Coefficients for the spline fit are often derived in a form as was used by Liou and Kurth. In this example embodiment, a different form is used. Hilbert integral equations are now developed for the cubic spline transition regions using a specific form of cubic spline coefficients. Liou and Kurth use a different form of spline coefficients, and another set of Hilbert integral equations may be easily derived for that form of the spline as well. In this example embodiment, each segment of the spline function is defined as
Â′(ω)=S(ω)=c₁(ω−ω₀)³+c₂(ω−ω₀)²+c₃(ω−ω₀)+c₄
where cₖ are coefficients determined by the spline fit algorithm, and a is the ordinate of the left side of the interval over which the fit is valid. The form of the Hilbert integral of the spline-function over the spline interval is:

$${I}_{S} ( ω ) = {\int }_{a}^{b} \frac{S ( η - a )}{η - ω} ⅆ η$$

The following derivation uses a to b to represent the end-points of a spline segment in the equations. Expanding the integral, and making the substitutions χ=η−a and φ=ω−a,

$${I}_{S} ( φ ) = {\int }_{0}^{b - a} \frac{S ( χ )}{χ - φ} ⅆ χ = {\int }_{0}^{b - a} \frac{{c}_{1} {χ}^{3} + {c}_{2} {χ}^{2} + {c}_{3} χ + {c}_{4}}{χ - φ} ⅆ x$$

where the cₖ represent cubic spline coefficients. Finally, integrating this yields

$${I}_{s} ( φ ) \frac{1}{6} ( ( b - a ) ( 6 {c}_{3} + 3 {c}_{2} ( a + b + 2 φ ) + {c}_{1} ( 2 {a}^{2} + 2 ab + 2 {b}^{2} + 3 ( a + b ) φ + 6 {φ}^{2} ) ) + ( {c}_{4} + φ ( {c}_{3} + φ ( c2 + c1 φ ) ) ) ln \vert a - φ \vert + ( {c}_{4} + φ ( {c}_{3} + φ ( c2 + c1 φ ) ) ) ln \vert b - φ \vert \\ {I}_{s} ( φ ) = \frac{1}{6} ( ( b - a ) ( 6 {c}_{3} + 3 {c}_{2} ( a + b + 2 φ ) + {c}_{1} ( 2 {a}^{2} + 2 ab + 2 {b}^{2} + 3 ( a + b ) ϑ + 6 {φ}^{2} ) ) + S ( φ ) ln \vert ( a - φ ) ( b - φ ) \vert$$

This yields the contribution to group delay due to a single spline segment. Each transition region is composed of two spline segments, so this formula is evaluated for each spline segment and the results summed to arrive at total contribution to group delay for the entire transition region. Contributions from multiple transition regions are summed to arrive at group delay contribution for all transition regions τ_{2B}.

For any given real world system, different extrapolation functions and transition behaviors may be designed. The only restriction to this example is that the user must be able to evaluate the Hilbert transform integral using these functions.

In operational block 215, the range of frequencies over which the system model is to be used is altered to exclude all frequency ranges over which transition regions have been designed. Accordingly, as described above, the smoothed transition region is used for computing contribution τ_{2B} to group delay over the transition region in operational block 216. Thus, contribution τ_{2B} is a second part of the second contribution τ₂ for the modeled region of the system, where such contribution τ_{2B} corresponds to the above-described transition region from the region for which measured amplitude data is known to the region for which such measured amplitude data is not known.

From operational block 213 or 216, operation advances to block 217 in which an algorithm is applied to compute a first part (τ_{2A}) of the second contribution τ₂ for the modeled region of the system, where such first part τ_{2A} corresponds to the remaining frequencies in the region for which such measured amplitude data is not known which are outside the above-described transition region. In block 217, the system model previously determined in block 209 or 211 (also shown as 109 of FIG. 1), is used to compute the first part of the second contribution (τ_{2A}) to group delay. The computation performed in block 217 is restricted to frequency ranges previously determined in block 207, and optionally modified in block 215. The system model previously determined may be a rough model when little is known about the network being measured. Accordingly, when the nominal design parameters of the system being measured are known, the rough model proposed by Liou and Kurth or rough generic model proposed herein may be replaced by a more flexible/accurate one. This is the case for example, when RF phase response of a signal generator (for example, the Agilent E8267C signal generator) is to be measured. Here, nominal design of the baseband generator and RF chain are well known (by those who designed the generator). It may be desirable to compensate for the nominal phase response as well as unit-to-unit and temperature variations.

This example embodiment replaces the rough model proposed by Liou and Kurth with a flexible, generic model capable of modeling a system having an arbitrary combination of poles and zeros. Typically, these poles and zeros will be chosen to match the nominal design or some other estimate of the electrical network. In accordance with one embodiment, a generalized algorithm is developed that allows each pole and zero to be treated independently. The result is that contributions to group delay and phase from each pole and zero may be separately computed and summed to provide the overall contribution for all frequencies outside the range of measured data.

The improved model may be configured to match the nominal design of known electrical components that contribute to phase non-linearity. For example, with signal generators modulated by internal digital-to-analog converters, the model might be chosen to match the nominal design for the baseband anti-alias filtering components. This would then be extended to include other known filters and devices in the signal generator's RF/microwave chain.

More particularly, in this example embodiment, to improve the accuracy of the algorithm used in block 217 for computing τ_{2A}, the estimate for system response outside the range of measured data is replaced with the nominal, designed response, specified in terms of poles and zeros:

$$H ( ω ) = \frac{{\prod }_{m = 1}^{M} ( j ω - {z}_{m} )}{{\prod }_{n = 1}^{N} ( j ω - {p}_{n} )} ,$$

wherein m is an integer, M is the number of zeros, n is an integer, and N is the number of poles.

In discussing the above system model, several changes of variable will be made below, so some functions will be shown with a suffix indicating the variable in which they are currently expressed. For use in the algorithm, the derivative of log-magnitude of this function is required. First, the log magnitude function is derived:

$${A}_{ω} ( ω ) = {\sum }_{m = 1}^{M} ln \vert j ω - {z}_{m} \vert - {\sum }_{n = 1}^{N} ln \vert j ω - {p}_{m} \vert$$

Although the derivative of the log magnitude function, A′(ω), has not yet been determined, it is clear that this will be a convenient form for use in the Hilbert integral, as the contribution of each pole and zero can be computed independently, and summed to arrive at the total group delay. Therefore, a system with a single zero will be considered and the results later extended to a generalized system with an arbitrary number of poles and zeros. In the formulas below z_{R} and z₁ represent the real and imaginary parts of the zero's location.

$$\begin{matrix}{A}_{ϖ} ( ω ) = ln \vert j ω - z \vert = ln \vert j ω - ( {z}_{R} + j {z}_{I} ) \vert = \frac{1}{2} ln ( {ω}^{2} - 2 {z}_{I} ω + {z}_{R}^{2} + {z}_{I}^{2} ) \\ {A}_{ω}^{′} ( ω ) = \frac{ⅆ A}{ⅆ ω} = \frac{1}{2} \frac{2 ω - 2 {z}_{I}}{{ω}^{2} - 2 {z}_{I} ω + {z}_{R}^{2} + {z}_{I}^{2}} = \frac{ω - {z}_{I}}{{ω}^{2} - 2 {z}_{I} ω + {z}_{R}^{2} + {z}_{I}^{2}}\end{matrix}$$

This can be simplified by letting χ=−z₁;

$$\begin{matrix}{A}_{χ}^{′} ( χ ) = ln \vert - {z}_{R} - j χ \vert = \frac{1}{2} ln ( {z}_{R}^{2} + {χ}^{2} ) \\ {A}_{χ}^{′} ( χ ) = \frac{χ}{{χ}^{2} + {z}_{R}^{2}}\end{matrix}$$

At this point, this model may be analytically, evaluated in the Hilbert integral. First, the indefinite integral is evaluated. For this case, the Hilbert integral is

$$H ( z , χ , η ) = \int \frac{{A}_{χ}^{′}}{η - χ} ⅆ η = \int \frac{η}{( {η}^{2} + {z}_{R}^{2} ) ( η - χ )} ⅆ η$$

This indefinite integral as evaluated by the Mathematica® software package

$$\begin{matrix}{H}_{χ} ( z , χ , η ) = \int \frac{η}{( {η}^{2} + {z}_{R}^{2} ) ( η - χ )} ⅆ η \\ = \frac{1}{{χ}^{2} + {z}_{R}^{2}} ( \vert {z}_{R} \vert {tan}^{- 1} \frac{η}{\vert {z}_{R} \vert} - \frac{χ}{2} ln [ {η}^{2} + {z}_{R}^{2} ] + \\ χ ln [ η - χ ] ) \\ = \frac{1}{{χ}^{2} + {z}_{R}^{2}} ( \vert {z}_{R} \vert {tan}^{- 1} \frac{η}{\vert {z}_{R} \vert} - χ ln \frac{\sqrt{{η}^{2} + {z}_{R}^{2}}}{\vert η - χ \vert} )\end{matrix} \qquad ( 1 )$$

Since the integral will be evaluated with an upper limit of infinity, it will be useful to note that

$${lim}_{{z}_{R \to 0}} {H}_{χ} ( z , χ , ξ ) = \frac{π}{2} \frac{{z}_{R}}{{χ}^{2} + {z}_{R}^{2}}$$

and since elliptic filters (ideally) have zeros on the imaginary axis, note that

$${lim}_{ξ \to ∞} {H}_{χ} ( z , χ , ξ ) = \frac{χ}{{χ}^{2} + {z}_{R}^{2}} ln \frac{\sqrt{{ξ}^{2} + {z}_{R}^{2}}}{\vert ξ - χ \vert} .$$

The formula for the indefinite integral in formula (1) above is evaluated for the two limits of integration and the results subtracted and divided by π to yield the contribution any specified range of frequencies.
H_{χ}(z,χ,[χ_{L} . . . χ_{H}])=H_{χ}(z,χ,χ_{H})−H_{χ}(z;χ,χ_{L})

By means of an example, the contribution to group delay due to a single pole or zero for frequencies outside the range of measurement may be computed by evaluating the summation of the following definite integrals. This example assumes that measured data is available over the range [ω₀ . . . ω_{N}], and χ=ω−z₁, χ₀=ω₀−z₁, χ_{N}=z₁, where ω is the frequency for which group delay or phase is to be computed. As discussed previously, measurement data may be available over more than one range of frequencies, in which case additional terms would be added to this equation:

$$ς ( z , χ ) = \frac{1}{π} [ {H}_{χ} ( z , χ , [ 0 … {χ}_{0} ] ) + {H}_{χ} ( z , - χ , [ 0 … {χ}_{0} ] ) + {H}_{χ} ( z , χ , [ {χ}_{N} … ∞ ] ) + {H}_{χ} ( z , - χ , [ {χ}_{N} … ∞ ] )$$

Extending the derivation to an approximation having an arbitrary number of poles and zeros, the total contribution to group delay for frequencies outside the range of measured data yields the equation for the term τ_{2A}:

$${\sum }_{m - 1}^{M} ς ( {z}_{m} , χ ) - {\sum }_{n - 1}^{N} ς ( {p}_{n} , χ )$$

An additional improvement in this technique, which is utilized in certain embodiments, is to optimize the generic system model to match actual measured data. Simple adjustments such as changing the models nominal center frequency and bandwidth to match measured data at the endpoints may be adequate in some situations.

In other cases, techniques such as genetic optimization and neural networks may be used. Here, the model is initialized to the nominal design values, then some or all of the pole/zero locations are modified as necessary to cause the model to be a better match to the measured data. This can have the effect of making the model a better match to actual system response at frequencies outside the range of measured data

In view of the above, the above-described application of the Hilbert transform is used in block 217 to compute the contribution τ_{2A} to group delay. From block 217, operation advances to block 218 whereat the first contribution τ₁ and second contribution parts τ_{2A} and τ_{2B} are summed to result in a total group delay, τ. That is, the contribution to group delay from the region of frequencies for which amplitude measurement data is known (τ₁) and the contribution to group delay from the remaining region of frequencies for which amplitude measurement data is not known (τ₂) are summed to compute the group delay τ.

From operational block 218, flow passes to operational block 219 (FIG. 2C) where information is received about the nature of the system being measured, specifically whether the system is minimum phase or not. As mentioned above, the Hilbert transform requires a non-minimum phase system. However, techniques are proposed herein that may be employed to enable the result of the Hilbert transform to be appropriately adjusted for an accurate computation of phase response for a non-minimum phase system. If the system is minimum phase, flow passes to block 220. If the system is non-minimum phase, flow passes to block 222 where the group delay data is numerically integrated to compute phase response. After block 222, flow passes to block 223 where the phase data is adjusted to properly reflect the non-minimum phase system, in the manner described further herein. At this point, a final corrected set of phase data is available. Flow passes to block 224 where a determination is made as to whether group delay information is desired. If not, flow passes to block 226 and the algorithm ends; otherwise, flow passes to block 225 where numerical differentiation of the phase information is performed to compute group delay. From block 225 flow passes to block 226 and the algorithm ends.

The following method can, in some cases, be used in block 223 to compute phase response for systems which fail to meet the minimum phase criteria of the Hilbert transform. This method works in those situations where the approximate location of right-half-plane (RHP) zeros are known, and can be made part of the system model. In this example embodiment, non-minimum phase systems containing right-half-plane poles are not considered. Since systems with RHP poles are unstable, they are difficult or impossible to measure. However, if the measurement obstacles can be overcome, these techniques may be applied to the measured data. Therefore, the discussion below applies equally to RHP poles and zeros.

Any non-minimum phase system, H, can be converted to a minimum phase system, Hₘ, by reflecting it's RHP zeros across the jω axis. For example, a complex zero pair at (+a±jb) is replaced with a complex zero pair at (−a±jb). The resulting transfer function will have an amplitude response identical to the original system, but the phase response is different. Applying the Hilbert transform to this amplitude response will generate the phase response for the minimum phase version of that system.

If the system model includes all significant RHP zeros, then it is still possible to use the Hilbert transform to compute phase response of the non-minimum phase system, using the following steps:
1. Compute phase response of the corresponding minimum phase system (Hₘ) by applying the Hilbert transform to amplitude response data. The Hilbert integral equations for system model extensions (τ_{2A}) only refer to the absolute value of the real part each zero, so it clearly makes no numerical difference in computing τ_{2A} if the model's RHP zeros have been converted to LHP zeros.
2. Create a new model consisting only of RHP zeros from the actual system model, Z. Create a second new model by converting the first new model to a minimum phase system Zₘ.
3. Compute the phase response of the two new models. Add the phase difference between these models (Z−Zₘ) to the result in step (1) to arrive at the phase of the non-minimum phase system.

In practice it is not necessary to compute the phase response of both models, through some simplifications. Phase adjustments are computed by evaluating the zero-only models at various points on the jω axis. For any zero in the model, phase angles to be subtracted at frequency ω are the angles of the vector (jω−Z)=(−Z_{R}+j(ω−Z₁)), and (+Z_{R}+j(ω−Z₁ which are given respectively by:

$$tan ( θ ) = \frac{w - {z}_{I}}{- {z}_{R}} and tan ( {θ}_{m} ) = \frac{w - {z}_{I}}{+ {z}_{R}} = - tan ( θ )$$

In the above equation, θ^{m} represents phase angle created by the minimum phase (LHP) zero and θ represents phase due to the RHP zero. Z_{R} is assumed positive. Given that the arc tangent is an odd function with period π, the following formula holds: tan(χ)=−tan(π−χ). Comparing this identity with the previous formula yields
θₘ=π−θ and θ−θₘ=2θ−π

As explained above, this technique requires knowledge of all significant RHP zeros in the system to be measured. In this context, “significant” means those zeros which have a measurable effect on non-linear phase or amplitude response.

In certain instances, the phase response may be desired, rather than or in addition to the group delay. Accordingly, block 220 determines whether phase response of the electrical network under analysis is desired to be computed. If not, then operation ends in block 226. On the other hand, if phase response is desired, operation advances to block 221 whereat numerical integration is performed on the group delay to compute the phase response. In the example operational flow of FIGS. 2A-2C, operation ends in block 226.

In many systems, a baseband system is shifted in frequency by means of multiplying the baseband time signal with a local oscillator.
r(t)=b(t)cos ω_{c}t=b(t)e^{jω}^{_{c}}^{t}+e^{-jω}^{_{c}}^{t})

In the frequency domain, this amounts to two copies of the original response being shifted in opposite directions and summed:
R(jω)=B(j(ω+ω_{c}))+B(j(ω−ω_{c}))

If B is a lowpass system and ω_{c} is sufficiently large compared to the bandwidth of the baseband system, B, R may be accurately analyzed by ignoring interactions between the two shifted baseband components. That is, the original set of poles and zeros are shifted in the positive direction by an amount equal to ω_{c} (the original set of poles and zeros is discarded). In other cases, for example when working with ultra-wideband signals and the frequency shift is small compared to the magnitude of poles and zeros in the system, this simplification may introduce significant errors in phase computation. To analyze this further, assume the baseband system, B is a ratio of two polynomials in jω, N and D: The system response after being multiplies by the local oscillator is:

$$R ( j ω ) = \frac{N ( j ( w - {w}_{c} ) )}{D ( j ( ω - {ω}_{c} ) )} + \frac{N ( j ( ω + {ω}_{c} ) )}{D ( j ( ω + {ω}_{c} ) )} \\ = \frac{N ( j ( ω - {ω}_{c} ) ) D ( j ( ω + {ω}_{c} ) ) + N ( j ( ω + {ω}_{c} ) ) D ( j ( ω - {ω}_{c} ) )}{D ( j ( ω - {ω}_{c} ) ) D ( j ( ω + {ω}_{c} ) )}$$

From this, it is evident that the translated system's poles are simply duplicated, and shifted in opposite directions; otherwise they are unchanged. It is not so simple with the zeros however. The zeros are now defined by the equation.
N(j(ω−ω_{c}))D(j(ω+ω_{c}))+N(j(ω+ω_{c}))D(j(ω−ω_{c}))=0

It will be necessary to expand the multiplicative terms to permit addition of the two polynomials before factoring the result to obtain zero locations. This transformation actually adds zeros to all-pole baseband systems. Unfortunately, some of these zeros can be right-half-plane zeros, which violates the minimum phase criteria required by the Hilbert transform. A method is presented above to deal with this problem.

Turning to FIG. 3, an example compute logic 30 that may be used in accordance with one embodiment for computing group delay and/or phase response is shown. Example compute logic 30 may be implemented in software, hardware, or a combination thereof. For instance, the various blocks of compute logic 30 described hereafter may be implemented in software, hardware, or a combination thereof. Compute logic 30 receives as inputs measured amplitude data 35 (e.g., scalar amplitude data 103 of FIG. 1), a corresponding list 36 of frequencies at which the measured amplitude data 35 was sampled (e.g., frequencies 104 of FIG. 1), and a list 37 of frequencies at which computation (e.g., of group delay and/or phase) is desired (e.g., list 115 of FIG. 1). In some instances, compute logic 30 may receive information 38 identifying locations of zeros and poles for the nominal design of the electrical network under analysis. In other cases, compute logic 30 ay receive a generic description 39 of the system indicating its nature (such as highpass, bandpass, lowpass, etc.), and some number of excess poles or zeros. Compute logic 30 may receive other such inputs as necessary to configure the system model used internally to simulate the network being measured. Compute logic 30 may output a computed group delay 350, 353 for the electrical network under analysis and/or a computed phase response 351, 352 for such electrical network.

Compute logic 30 includes first logic 31 that computes a first contribution τ₁ to the group delay, such contribution being made by measured amplitude data, such as described above with operational block 206 of FIG. 2A. Compute logic 30 further includes second logic 32 that computes a second contribution τ₂ to the group delay, such second contribution made by the modeled portion of the system (i.e., the portion for which measured amplitude data is not received). Second logic 32 includes logic 320 to set the system model usage ranges to include all frequency ranges not present in the measured amplitude data (as in operational block 207 of FIG. 2B). Second logic 32 further includes logic 321 to determine whether locations of poles and zeros are known (as in operational block 208 of FIG. 2B). That is, logic 321 determines whether information 38 is available. If such information is available to compute logic 30, then operation of second logic 32 advances to block 322 to receive the known locations of poles and zeros in the system model for computing contribution τ₂, such as described above in connection with operational block 209 of FIG. 2B.

If logic 321 determines that information 38 is not available to compute logic 30, then operation of second logic 32 advances to block 323. In block 323, general system information 39 is received (as described above in operational block 210 of FIG. 2B). Flow then passes to block 324 where the general system information is used to construct a rough system model as is done in block 211 of FIG. 2B. Flow then passes out of blocks 322 and 324 into block 325. In block 325, a determination is made whether transition regions are desired (as in block 212 of FIG. 2B). This determination may be made with information received from the outside about the desired use of transition regions, or analysis of the measured data and system model can be used to make this determination. If transition regions are not desired, flow passes to block 326 where the contribution from transition regions (τ_{2B}) is set to zero (as in block 213 of FIG. 2B).

In the case where transition regions are desired, flow passes to block 327. In block 327, a smooth transition segment utilized in the system model of the region for which measured amplitude data is not received, such as discussed above with block 214 of FIG. 2B. Such smoothed transition segment is used in block 328 to compute a second part τ_{2B} of the second contribution τ₂, such second part resulting from the model of the transition segment, as discussed above with block 216 of FIG. 2B. From block 328, flow passes to block 329, where the range(s) of frequencies to be modeled by the system model is modified to exclude those ranges of frequencies containing smoothed transition segments, as in block 215 of FIG. 2B. Flow then passes from blocks 326 and 329 into block 330. In block 330, a first part τ_{2A} of the second contribution τ₂ is computed, such first part resulting from the model of the remaining frequencies for which amplitude measurements are not received, as discussed above with block 217 of FIG. 2B. Operation 331 sums the two parts τ_{2A} and τ_{2B} to result in the second contribution τ₂ to group delay.

Logic 33 is included, which receives the first computed contribution τ₁ from logic 31 and the second computed contribution τ₂ from logic 32, and logic 33 sums the received contributions τ₁ and τ₂ to result in the group delay τ, such as with operational block 218 of FIG. 2B.

Phase compute logic 34 is also included, which includes operational block 341 for determining whether a non-minimum phase system is being measured, as in operational block 219 of FIG. 2C. If the system is minimum phase, group delay may be output as 350, if desired, and flow passes to block 342 for determining whether computation of phase response is desired, as in block 220 of FIG. 2C. If phase response is not desired, operation ends in block 348. If computation of phase response is desired, operation advances to block 343 whereat numerical integration on the computed group delay τ is performed to compute phase, as discussed above with block 221 of FIG. 2C. The computed phase response may, if desired, be output as output 351.

In the case of a non-minimum phase system, flow passes from block 342 to block 343 where the group delay is converted to phase response of the corresponding minimum phase system, as in block 222 of FIG. 2C. Flow then passes to block 345 where adjustments are made to the phase to correct for the non-minimum phase nature of the system, as described above with block 223 of FIG. 2C. At this point, phase may be output as output 352 if desired. Flow passes from block 345 to block 346 where a determination is made whether group delay is desired, as in block 224 of FIG. 2C. If group delay is not desired, computation ends in block 348; otherwise flow passes to block 347 where the phase data is numerically differentiated to obtain group delay (as in block 225 of FIG. 2C), which may be output as output 353.

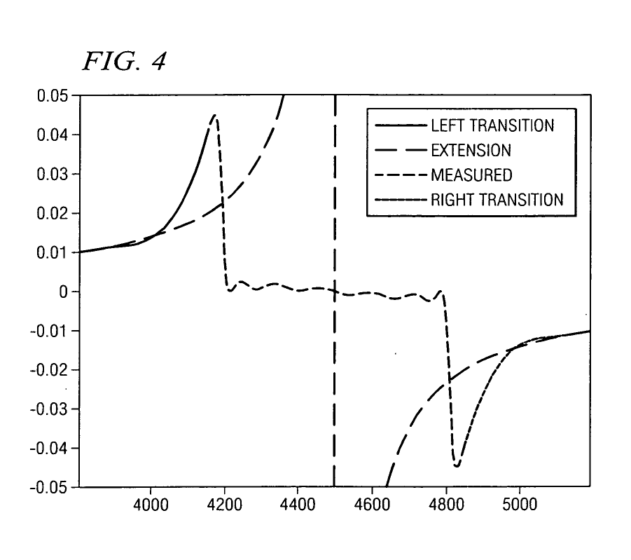

Turning to FIG. 4, this shows a graph demonstrating how computations are improved by addition of transition regions. This graph plots frequency in the X-axis and DLM (derivative of log-magnitude) in the Y-axis. There are four distinct curves on this plot. The first, central curve displays measured amplitude data. The curve labeled “Extension” is the DLM of the rough, extended system model. Notice how the endpoints of measured data fail to line up with the extension curve. The last two curves show the transition curves added which create a smooth transition between measured data and the extension.

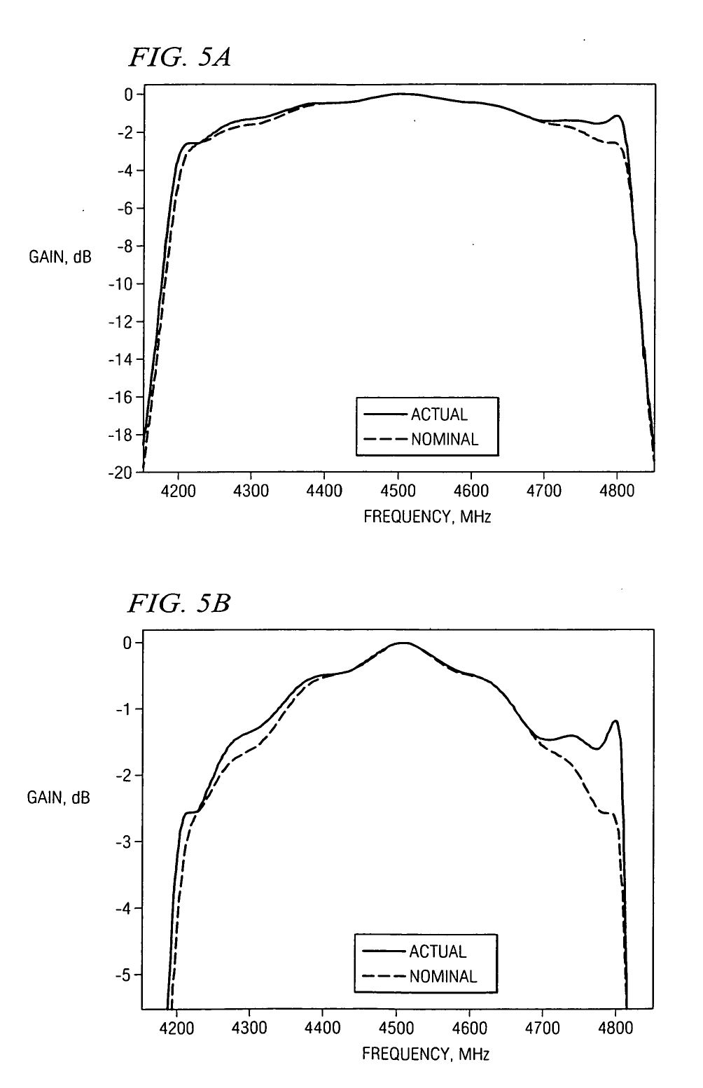

FIGS. 5A and 5B show graphs illustrating a simulation of nominal amplitude response versus actual simulated response. The test of this example, is modeling a lowpass system with an approximate bandwidth of 300 MHz, up-converted to a center frequency of 4500 MHz. The nominal baseband system includes a 7^{th} order Chebyshev lowpass filter cascaded with a one-pole lowpass filter (where the pole is located at 325 MHz). The Chebyshev filter was designed using 0.2 dB ripple and a 300 MHz cutoff frequency (i.e., 0.2 dB down at 300 MHz).

Hilbert transforms were computed using a rough model having eight poles located at +j4500 MHz. Additionally, the improved system model described above was setup with the exact pole locations in the nominal design.

The nominal system was then modified by moving pole locations in both magnitude and phase by random amounts up to 2.5% of their original values to simulate component variations. Thus, one plot (the “nominal” plot) shows the amplitude response of the nominal ideal system, and the other plot (the “actual” plot) shows the response of the system as it was “tweaked” to represent typical component variations. The actual (“tweaked”) system represents what might be seen in the real world when temperature and component variations occur.

Data was simulated over a range of 700 MHz, which goes about 20 dB down on the filter skirts. The actual response data was fed into the Hilbert transform algorithm, using five different techniques:
1. The original method as proposed by Liou and Kurth, with α and β set to 8; and
2. The original method as proposed by Liou and Kurth, modified for use with a translated bandpass system by shifting the 8 poles at zero frequency to the bandpass center frequency and discarding all zeros; and;
3. the above-described modified method with the addition of matching conjugate poles on the −jω axis; and
4. The above-described modified method using transition regions between measured data and the simple system model (that is, computing τ₂ as described above with operational blocks 320-331 of FIG. 3; and
5. The technique using a system model that includes knowledge (e.g., information 38 of FIG. 3) of locations of poles and zeros of the nominal system design, as described above with block 209 of FIG. 2B.

The phase computed by each of these three techniques was then compared to the actual phase response of the altered system to generate error data. FIGS. 6A-6B show the phase error between various techniques and the actual system phase response for the amplitude measurement data of FIGS. 5A-5B. Here, as is typical in many cases, phase was only computed over the same range of frequencies that measurement data was available over. As has been previously discussed, it is possible to use the techniques described herein to compute phase at frequencies outside the range of frequencies over which measured data is available; however in many cases error levels will increase as frequencies depart from those where measurement data was taken.

In FIGS. 6A and 6B, five plots of phase error versus frequency are shown. The Y-axis in FIG. 6B is magnified by a factor of 10 over that in FIG. 6A. The five curves correspond to the phase error computed for each of the five techniques described above. As shown, peak error values are reduced about 4:1 over the Liou and Kurth technique with a system model containing only poles on the +ω axis at the center frequency of the bandpass system. Adding transition segments to the improved model further reduces errors by 4:1. This error is further reduced by approximately 3:1 when the nominal system model is used. Comparing errors in the original Liou and Kurth technique to those resulting when the nominal system model is used, a reduction of nearly 50:1 is achieved. Notice that changing from poles on the +jω axis (2nd example) to conjugate pole pairs (3rd example) slightly increases the error level. This demonstrates the important of including zeros that are created by the frequency translation process (as derived elsewhere herein). Although not shown, adding the missing zeros to the simulation, and correcting for the RHP (non-minimum phase) zeros returned errors to the level of the second example. It did not improve beyond the second example due to the large relative amount of frequency translation (4500 MHz compared to the 300 MHz bandwidth of the lowpass system). Simulations were conducted where the relative shift was much smaller (600 MHz for example), and in this case it was mandatory to include the extra zeros as well as perform corrections for the non-minimum phase portion of the system to achieve equivalent error levels. One degree corresponds to 0.0175 radian, and FIGS. 6A-6B show that using the “Full Model” technique yields errors that are just a fraction of a degree. Attempts to improve the Liou and Kurth technique by varying the values of α and β yielded no significant improvement in phase error

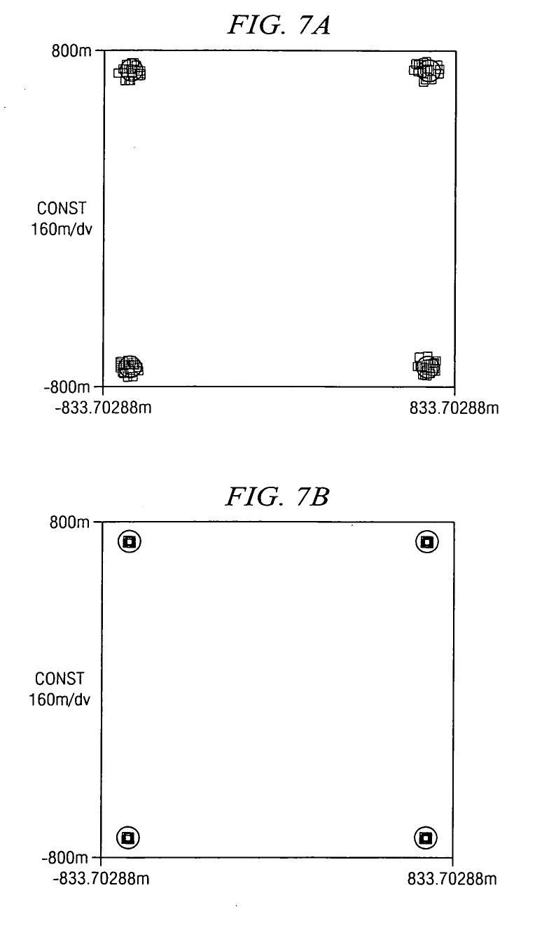

FIGS. 7A and 7B depict graphs providing further proof of the value of the techniques described herein. For this demonstration, digital modulation, namely QPSK (Quadrature Phase Shift Keying), was placed onto an RF carrier signal. An Agilent signal generator, E8267C with digital modulation option was used to generate the signal at a 500 MHz carrier frequency. Random QPSK symbols were generated at a rate of 50 M-symbols/sec with the internal waveform generator's DACs running at a 100 M-sample/sec sample rate. The digital waveform was filtered with a root-raised-cosine filter such that the occupied bandwidth was approximately 80 MHz.

A system model that included the signal generator's baseband reconstruction filters and a few other significant components was used in converting measured amplitude response into phase. The arithmetic inverse of the resulting phase data was used to generate an FIR digital filter. This filter was subsequently used to pre-distort the QPSK waveform.

The resulting RF signal was received with an Agilent Infiniium oscilloscope, which had been previously calibrated by independent techniques. The oscilloscope phase response was flat to within one degree or better in an 80 MHz bandwidth centered around 500 MHz. Finally, Agilent “Glacier” software (model number 89600) was used to demodulate and analyze the QPSK signal. “Glacier” software is capable of measuring Error Vector Magnitude, or EVM of the QPSK signal. This is an indication of how precisely the modulation symbols are generated. Achieving low EVM requires a system be accurate in phase and magnitude over the entire occupied bandwidth of the signal, 80 MHz in this case. EVM is commonly measured as the percentage ratio of the length of the error vector to the length of the ideal symbol. The error vector is the vector from the ideal symbol to the actual received symbol.

Measurements were made with an uncorrected QPSK signal, as shown in FIG. 7A. The graph depicts the measured location of 250 random QPSK symbols, where each symbol is shown as a rectangle. In the ideal case, with zero EVM, each rectangle appears in only one of four desired locations: all rectangles at a given location are exactly on top of each other and the plot appears to contain only one rectangle at each location. As is visible in FIG. 7A, the rectangles are spread out considerably from the ideal locations and many different rectangles are visible at each location. In this case, the average EVM of the depicted symbols was 3.4%. For this measurement, amplitude flatness corrections had been applied to the signal, such that any remaining EVM would be due to non-linear phase errors in the signal generator or oscilloscope, or noise and distortion products in various parts of the system.

FIG. 7B depicts the EVM measurement after the signal's phase was corrected by pre-distorting the digital waveforms with the arithmetic inverse of computed phase. Clearly, all of the rectangles are now much more nearly on top of each other, as confirmed by the EVM measured in this case of 0.7%.

Although the present invention and its advantages have been described in detail, it should be understood that various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one will readily appreciate from the disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

1. A method comprising:
using measured data and a model that includes information regarding location of at least one of (a) at least one pole and (b) at least one zero for an electrical network for computing at least one of group delay and phase response of said electrical network.

2. The method of claim 1 wherein said electrical network is of any type selected from the group consisting of:
lowpass, highpass, bandstop, bandpass, allpass, and translated versions thereof.

3. The method of claim 1 wherein said information includes information regarding locations of at least one pole and at least one zero known for said electrical network.

4. The method of claim 1 wherein said information regarding location includes information identifying approximate location of said at least one of (a) at least one pole and (b) at least one zero for said electrical network.

5. The method of claim 1 wherein said information regarding location is information regarding location of said at least one of (a) at least one pole and (b) at least one zero for a nominal design of said electrical network.

6. The method of claim 1 wherein said electrical network comprises a plurality of interconnected electrical components.

7. The method of claim 6 wherein said plurality of interconnected electrical components comprise at least one selected from the group consisting of: resistor, capacitor, inductor, semiconductor, integrated circuit, and transmission line.

8. The method of claim 1 wherein said computing at least one of group delay and phase response comprises:
computing, for said electrical network, a first contribution to group delay for a first range of frequencies over which said measurement data is known;
determining a transition region of frequencies between said first range of frequencies and said range of frequencies for which said model is used; and
computing, for said electrical network, a second contribution to group delay for said transition region.

9. The method of claim 8 wherein said computing said second contribution to group delay for said transition region comprises:
using a cubic spline fit for said transition region.

10. The method of claim 8 wherein said computing said second contribution to group delay for said transition region comprises:
using a mathematical function for transitioning from said first range of frequencies to said range of frequencies for which said model is used in a manner that can be evaluated by a Hilbert integral.

11. The method of claim 1 wherein said computing at least one of group delay and phase response comprises:
computing, for said electrical network, a first contribution to group delay for a first range of frequencies over which said measurement data is known.

12. The method of claim 11 wherein said using said model comprises:
using said model for computing a second contribution to group delay for said range of frequencies over which said measurement data is not known.

13. The method of claim 12 further comprising:
summing said first contribution and said second contribution to compute group delay for said electrical network.

14. The method of claim 13 further comprising:
performing numerical integration on said computed group delay to determine phase response of said electrical network.

15. The method of claim 1 wherein said electrical network is a non-minimum phase system.

16. The method of claim 15 further comprising:
computing an adjustment to phase response for said non-minimum phase system.

17. The method of claim 1 wherein said electrical network is a linear system.

18. A method comprising:
determining a transition segment for transitioning between a first region of frequencies for which amplitude measurement data is known for an electrical network under analysis and a second region of frequencies for which amplitude measurement data is unknown; and
computing a first contribution to group delay of said electrical network over said second region of frequencies using the determined transition segment.

19. The method of claim 18 wherein said computing said first contribution to group delay for second region comprises:
using a cubic spline fit for said second region.

20. The method of claim 18 wherein said computing said first contribution to group delay for said second region comprises:
using a mathematical function for transitioning in a manner that can be evaluated by a Hilbert integral from said first range of frequencies to a third range of frequencies for which amplitude measurement data is not known.

21. The method of claim 18 further comprising:
computing, for said electrical network, a second contribution to group delay for said first region of frequencies over which amplitude measurement data is known; and
using a model for computing a third contribution to group delay for said second region of frequencies over which amplitude measurement data is not known, wherein said transition segment transitions between said first region and said second region.

22. The method of claim 21 wherein said model includes information regarding location of at least one of (a) at least one pole and (b) at least one zero for said electrical network.

23. The method of claim 22 wherein said information regarding location comprises information identifying approximate location of said at least one of (a) at least one pole and (b) at least one zero in a nominal design of said electrical network.

24. The method of claim 21 further comprising:
summing the first, second, and third contributions to group delay to compute a total group delay for said electrical network.

25. The method of claim 24 further comprising:
determining phase response of the electrical network from the total group delay.

26. The method of claim 25 wherein said determining phase response comprises:
performing numerical integration of the total group delay.

27. The method of claim 18 further comprising:
determining if said electrical network is a non-minimum phase system.

28. The method of claim 27 wherein if determined that said electrical network is a non-minimum phase system, computing an adjustment to said phase response for said non-minimum phase system.

29. The method of claim 28 further comprising:
computing group delay for said non-minimum phase system.

30. The method of claim 29 wherein said computing group delay for said non-minimum phase system comprises:
numerically differentiating the phase response determined for said non-minimum phase system.

31. Computer-executable software code stored to a computer-readable medium, said computer-executable software code comprising:
code for receiving amplitude measurement data for an electrical network for at least a first range of frequencies;
code for computing a first contribution to group delay for the at least a first range of frequencies;
code for receiving information regarding location of at least one of (a) at least one zero and (b) at least one pole known for said electrical network; and
code for using the received location information for computing a second contribution to group delay for at least a second range of frequencies that are outside the at least a first range.

32. The computer-executable software code of claim 31 further comprising:
code for determining if said location information is available, and triggering execution of said code for receiving said location information and said code for using said location information if said location information is determined to be available.

33. The computer-executable software code of claim 32 further comprising:
code for creating a rough model if determined that said location information is not available.

34. The computer-executable software code of claim 33 wherein said code for creating a rough model comprises code for receiving information identifying the type of said electrical network and code for receiving information specifying at least one of (a) a number of excess poles and (b) a number of excess zeros of said electrical network.

35. The computer-executable software code of claim 34 wherein said code for creating a rough model creates a model corresponding to the type of said electrical network based at least in part on at least one of the number of excess poles and the number of excess zeros.

36. The computer-executable software code of claim 31 further comprising:
code for summing the computed first and second contributions to compute group delay for said electrical network.

37. The computer-executable software code of claim 36 further comprising:
code for performing numerical integration on the computed group delay to compute phase response for said electrical network.

38. The computer-executable software code of claim 31 further comprising:
code for using a transition segment for computing a third contribution to group delay for at least a third range of frequencies that are between said first range and said second range of frequencies.

39. The computer-executable software code of claim 38 further comprising:
code for summing the computed first, second, and third contributions to compute group delay for said electrical network.

40. The computer-executable software code of claim 31 further comprising:
code for determining if said electrical network is a non-minimum phase system.

41. The computer-executable software code of claim 40 further comprising:
code for computing phase response for said electrical network if determined that said electrical network is a non-minimum phase system.

42. The computer-executable software code of claim 41 further comprising:
code for computing group delay for said non-minimum phase system.

43. A method comprising:
computing, for an electrical network under analysis, a first contribution to group delay for a first range of frequencies for which amplitude measurement data is known; and
computing, for said electrical network, a second contribution to group delay for a second range of frequencies for which amplitude measurement data is not known, wherein said computing said second contribution comprises computing a first part of said second contribution corresponding to a transition region from said first range to said second range.

44. The method of claim 43 wherein said computing said first part of said second contribution comprises:
using a cubic spline fit for said transition region.

45. The method of claim 43 further comprising:
computing, for said electrical network, a second part of said second contribution to group delay using a model for said electrical network over a range of frequencies for which amplitude measurement data is not known.

46. A system comprising:
logic operable to determine at least one of group delay and phase response for a non-minimum phase electrical network.

47. The system of claim 46 further comprising:
logic operable to receive, for said non-minimum phase electrical network, amplitude measurement data for at least a first range of frequencies; and
logic operable to compute a first contribution to an initial group delay for said at least a first range of frequencies.

48. The system of claim 47 further comprising:
logic operable to receive a system model for modeling at least a second range of frequencies for which amplitude measurement data is not received; and
logic operable to compute a second contribution to an initial group delay for said at least a second range of frequencies.

49. The system of claim 48 wherein said system model comprises information regarding locations of at least one of zeros and poles of said electrical network.

50. The system of claim 49 wherein said information regarding locations comprises information identifying approximate locations of said at least one of zeros and poles of a nominal design of said electrical network.

51. The system of claim 48 further comprising:
logic operable to sum the computed first and second contributions to compute an initial group delay;
logic operable to compute an initial phase response from said initial group delay; and
logic operable to compute an adjustment to said initial phase response to determine phase response for said non-minimum phase system.

52. The system of claim 51 further comprising:
logic operable to determine group delay for said non-minimum phase system from said determined phase response for said non-minimum phase system.

53. The system of claim 52 wherein said logic operable to determine group delay comprises:
logic operable to numerically differentiate said determined phase response for said non-minimum phase system to compute said group delay for said non-minimum phase system.

54. The system of claim 46 further comprising:
logic operable to determine that said electrical network is a non-minimum phase system.

55. A system comprising:
means for determining a type of an electrical network under analysis, wherein said type is any of various types selected from the group consisting of lowpass, highpass, bandstop, bandpass, allpass, and translated versions thereof; and
means for computing at least one of group delay and phase response for the electrical network of the determined type.

56. The system of claim 55 wherein said electrical network is a translated bandpass system.

57. The system of claim 55 wherein said electrical network is one selected from the group consisting of highpass, bandstop, and allpass.

58. The system of claim 55 wherein said means for computing at least one of group delay and phase response comprises:
means for computing, for said electrical network, a first contribution to group delay for at least a first range of frequencies for which amplitude measurement data is known.

59. The system of claim 58 wherein said means for computing at least one of group delay and phase response comprises:
means for modeling said electrical network over at least a second range of frequencies for which amplitude measurement data is not received; and
means for computing from said model a second contribution to group delay for said at least a second range of frequencies.

60. The system of claim 59 wherein said means for modeling said electrical network comprises information regarding locations of at least one of zeros and poles of said electrical network.

61. The system of claim 59 wherein said means for computing at least one of group delay and phase response comprises:
means for summing the computed first and second contributions to compute group delay for said electrical network.

62. The system of claim 61 wherein said means for computing at least one of group delay and phase response comprises:
means for computing phase response of said electrical network from said computed group delay.
